(19) United States
(12) Patent Application Publication
(10) Pub. No.: US 2026/0047104 A1
(43) Pub. Date: Feb. 12, 2026

(54) SEMICONDUCTOR DEVICE AND METHOD OF FORMING THEREOF

(71) Applicant: TAIWAN SEMICONDUCTOR MANUFACTURING COMPANY, LTD., Hsinchu (TW)

(72) Inventor: Ching-Pei HSIEH, Kaohsiung City (TW)

(73) Assignee: TAIWAN SEMICONDUCTOR MANUFACTURING COMPANY, LTD., Hsinchu (TW)

(21) Appl. No.: 18/799,306

(22) Filed: Aug. 9, 2024

(51) Int. Cl. H10B 63/00; H10N 70/00; H10N 70/20

(52) U.S. Cl. CPC H10B 63/00; H10N 70/066; H10N 70/24; H10N 70/8265

(57) ABSTRACT

A method of forming a semiconductor device includes a number of operations. A first inter-metal dielectric (IMD) layer is formed over a first metal line. An opening is formed in the first IMD layer. A bottom electrode layer is formed in the opening of the first IMD layer. A first spacer layer is formed over the bottom electrode layer. The first spacer layer is etched to form first spacers within the opening in the first IMD layer. A resistive dielectric layer is formed over the bottom electrode layer and the first spacers. A top electrode is formed over the resistive dielectric layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

In integrated circuit (IC) devices, resistive random access memory (RRAM) is an emerging technology for next generation non-volatile memory devices. RRAM is a memory structure including an array of RRAM cells each of which stores a bit of data using resistance values. Particularly, RRAM cell includes a resistive material layer, the resistance of which can be adjusted to represent logic “0” or logic “1.”

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross sectional view of a resistive random access memory (RRAM) device with a TEVA and BEVA in accordance with some embodiments of the present disclosure.

FIG. 2 illustrates a cross sectional view of a RRAM cell of the RRAM device of FIG. 1 in accordance with some embodiments of the present disclosure.

FIGS. 3 through 9 illustrate cross-sectional views of formation of a RRAM cell in accordance with some embodiments of the present disclosure.

FIGS. 10 through 14 illustrate cross-sectional views of formation of a RRAM cell in accordance with some embodiments of the present disclosure.

FIG. 15 illustrates a top view of a RRAM device in accordance with some embodiments of the present disclosure.

FIGS. 16A through 16C illustrate top views of RRAM cells in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Integrated memory refers to memory technologies that are built directly onto a microchip or integrated circuit, rather than being separate or “discrete” components. One such technology is Resistive Random Access Memory (RRAM), also known as ReRAM (Resistive RAM) or memristor-based memory. RRAM is a non-volatile memory technology that has benefits including high density, low power, and fast access.

RRAM operates on a principle of resistive switching. RRAM uses materials that can change their resistance state between a high-resistance (OFF) state and a low-resistance (ON) state in response to an applied voltage. These materials typically have a thin insulating layer sandwiched between two electrodes. By applying voltage pulses of selected magnitudes, the resistance of the insulating layer can be switched between its different states. RRAM is a non-volatile memory technology, which means it retains stored data even when power is turned off. RRAM devices use relatively low power to switch their resistance states, which can contribute to energy-efficient operation in integrated circuits. RRAM devices have the potential to offer fast read and write access times compared to some other non-volatile memory technologies, making them suitable for applications requiring quick data retrieval. RRAM that can be integrated in advanced semiconductor manufacturing processes is beneficial to integration into modern microchips without major modifications to an existing fabrication process. A planar memory device may include two separate planar devices, including a single transistor (1T) and a single resistor (1R) that are typically positioned in two separate metal layers as electrodes. Hence, device density increases become difficult.

A RRAM cell may have conductive interconnects including a top electrode via (TEVA) and a bottom electrode via (BEVA) that connects the top and bottom electrodes to the rest of a RRAM device. In one or more embodiments of the present disclosure, the RRAM cell including top and bottom electrodes and insulating layer sandwiched between the top and bottom electrodes may be formed in the BEVA level so that the size of the RRAM cell can be shrank and the RRAM cell density in the RRAM device may be increased. In some embodiments, the formed RRAM cell embedded in the BEVA level may include spacer layers between the bottom electrode and the insulating layer and damage caused by dry etch process to the spacer and can be reduced.

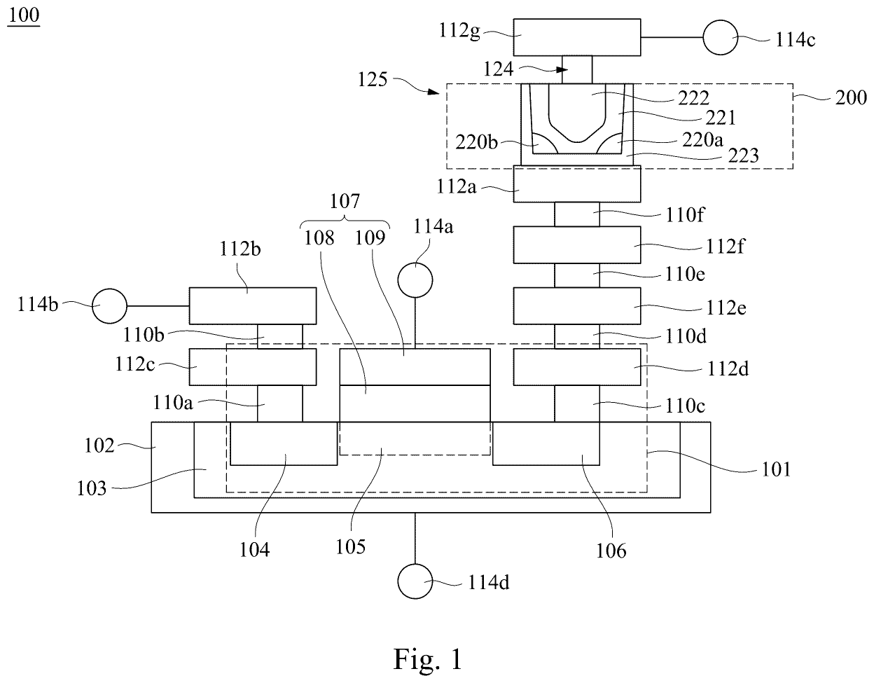

FIG. 1 illustrates a cross sectional view of a resistive random access memory (RRAM) device 100 with a top electrode via (TEVA) 124 and a bottom electrode via (BEVA) 125 in accordance with some embodiments of the present disclosure. As illustrated in FIG. 1, the RRAM device 100 may include a RRAM cell 200 within the BEVA 125. In some embodiments, a plurality of such RRAM devices form a memory array configured to store data.

In one or more embodiments, a selection transistor is associated with each RRAM device. The selection transistor is configured to suppress sneak-path leakage (i.e., prevent current intended for a particular memory cell from passing through an adjacent memory cell) while providing enough driving current for memory cell operation. In one or more embodiments, the RRAM device 100 includes a planar MOSFET selection transistor 101 and a RRAM cell 200. The RRAM cell 200 is electrically connected to the transistor 101.

As illustrated in FIG. 1, the RRAM device 100 includes a substrate 102. The substrate 102 may be a semiconductor substrate, such as a bulk semiconductor, or the like, which may be doped (e.g., with a p-type or an n-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; other compound semiconductors including gallium, zinc, indium and/or oxygen; or combinations thereof. Other substrates, such as single-layer, multi-layered, or gradient substrates may be used.

The selection transistor 101 is formed over the substrate 102. In one or more embodiments of the present disclosure, t he transistor 101 includes a semiconductor well 103 formed in the substrate 102. For example, the semiconductor well 103 may be doped with impurities to form either n-type (with donor impurities like phosphorus or arsenic) semiconductor for NMOS or p-type (with acceptor impurities like boron) semiconductor for PMOS.

The transistor 101 may further include source/drain regions 104 and 106 and a channel region 105 in the semiconductor well 103. In FIG. 1, the source/drain regions 104 and 106 may be heavily doped regions in the semiconductor well 103 of the substrate 102. The channel region 105 between the source/drain regions 104 and 106 is lightly doped with the opposite conductive type of impurity compared to the source/drain regions 104 and 106. For example, an NMOS may have a p-type channel (e.g., with boron), and a PMOS may have an n-type channel (e.g., with phosphorus). In some embodiments, the source/drain regions 104 and 106 are doped with carbon.

As illustrated in FIG. 1, the transistor 101 may include a gate structure 107 over the substrate 102. The gate structure 107 may include a gate dielectric layer 108 extending laterally over the surface of the channel region 105 of the semiconductor well 103 and a gate electrode 109 over the gate dielectric layer 108. The gate electrode 109 is separated from the source/drain regions 104 and 106 by the gate dielectric layer 108. In some embodiments, the gate dielectric layer 108 may be or include silicon dioxide (SiO₂) or a high-k dielectric, such as hafnium oxide (HfO₂) that is beneficial to reduce leakage and improve performance. In some embodiments, the gate electrode 109 may include suitable conductive material such as metal material or poly silicon.

The RRAM device 100 may be selectively accessed using word lines and bit lines for reading, writing and erasing operations. In one or more embodiments of the present disclosure, one or more metal lines including metal lines 112c, 112d, 112e, 112f and metal vias include metal vias 110a, 110b, 110c, 110d, 110e, 110f that helps in connecting the RRAM device 100 with the external circuitry may be present between the source/drain region 106 and the metal line 112a, and the source/drain region 104 and the metal line 112b. In some embodiments, the metal lines 112a, 112b, 112c, 112d, 112e, 112f may include copper (Cu) or other suitable conductive material.

In FIG. 1, the source/drain region 106 is connected to a data storage element or RRAM cell 200 by way of a first metal line 112a. The source/drain region 104 is connected by way of a second metal line 112b. The gate electrode 109 of the gate structure 107 is connected to a word line 114a, the source/drain region 104 is connected to a select line 114b through the second metal line 112b and the RRAM cell 200 is further connected to a bit line 114c within an upper metallization layer by way of an additional metal line 112g. In some embodiments, the semiconductor substrate 102 may be connected to a substrate line 114d.

In one or more embodiments of the present disclosure, as illustrated in FIG. 1, the RRAM device 100 further includes a top electrode via (TEVA) 124 and a bottom electrode via (BEVA) 125, and the RRAM cell 200 of the RRAM device 100 is embedded in the BEVA 125. The TEVA 124 connects the RRAM cell 200 in the BEVA 125. The metal line 112a is wider than the overlaying RRAM cell 200 in the BEVA 125.

As illustrated in FIG. 1, in one or more embodiments of the present disclosure, the RRAM cell 200 may include a top electrode 222, a bottom electrode 223 and a resistance switchable layer 221 sandwiched between the top electrode 222 and the bottom electrode 223. In some embodiments, the top electrode 222 and the bottom electrode 223 may include titanium (Ti), tantalum (Ta), titanium nitride (TiN), tantalum nitride (TaN), other suitable conductive material or metal composite films. In some embodiments, the material of the top electrode 222 and the bottom electrode 223 is different from the material of the metal lines such as metal line 112a and the TEVA 124.

In some embodiment, the resistance switchable layer 221 may include a thin insulating layer such as a variable resistive dielectric layer between the top electrode 222 and the bottom electrode 223. The variable resistive dielectric layer is normally insulating, but a sufficient voltage applied to the variable resistive dielectric material will form one or more conductive pathways in the variable resistive dielectric. Through the appropriate application of various voltages (e.g. a set voltage and reset voltage), the conductive pathways may be modified to form a high resistance state or a low resistance state. The variable resistive dielectric layer is one that can be induced to undergo a reversible phase change between a high resistance state and a low resistance state. In some embodiments, the change is between an amorphous state and a metallic state. The phase change can be accompanied by or associated with a change in molecular structure. For example, an amorphous metal oxide may lose oxygen as it undergoes a phase change to a metallic state. The oxygen may be stored in a portion of Variable resistive dielectric layer that remains in the amorphous state or in an adjacent layer. Variable resistive dielectric layer is described as dielectric with reference the high resistance state. In the low resistance state, variable resistive dielectric layer may be a conductive material. For example, in the low resistance state, the variable resistive dielectric layer may include a high-k dielectric with one or more conductive filaments that extend from the bottom electrode to the top electrode, wherein these filaments effectively render the variable resistive dielectric layer conductive. In some embodiments, these filaments are broken in the low resistance state, such that the variable resistive dielectric layer is a high-k dielectric that fully separates the top electrode 222 and bottom electrode 223 while in the high resistance state. In some embodiments, variable resistive dielectric layer is a transitional metal oxide. Examples of materials that can be suitable for Variable resistive dielectric layer include NiOₓ, Ta_{y}Oₓ, TiOₓ, HfOₓ, WOₓ, ZrOₓ, Al_{y}Oₓ, and SrTiOₓ.

In some embodiments, the resistance switchable layer 221 may include a capping layer. A capping layer may provide an oxygen storage function that facilitates phase changes within resistance switchable layer 221. In some embodiments, the capping layer is a metal or a metal oxide that is relatively low in oxygen concentration. Examples of metals that can be suitable for a capping layer include Ti, Hf, Pt and Al. Examples of metal oxides that can be suitable for capping layer include TiOₓ, HfOₓ, ZrOₓ, GeOₓ, CeOₓ. A capping layer can have any suitable thickness.

As illustrated in FIG. 1, the bottom electrode 223 is directly over the metal line 112a and has an U-shaped profiled. The resistance switchable layer 221 is formed in the bottom electrode 223. The top electrode 222 is filled with a recess of the resistance switchable layer 221. In one or more embodiments of the present disclosure, the RRAM cell 200 further includes spacers 220a and 220b between the resistance switchable layer 221 and the bottom electrode 223. The spacers 220a and 220b are located on opposite inner sidewalls of the bottom electrode 223 and spaced apart from each other. The resistance switchable layer 221 extends through a gap between the spacers 220a and 220b so that the bottom electrode 223 has a horizontal portion between the resistance switchable layer 221 and the metal line 112a. Both of t he spacers 220a and 220b are spaced apart from the top electrode 222 by the resistance switchable layer 221. In some embodiments, a material of the spacers 220a and 220b may include silicon nitride (SiN), silicon carbide (SiC), silicon oxynitride (SiON) or any suitable dielectric material.

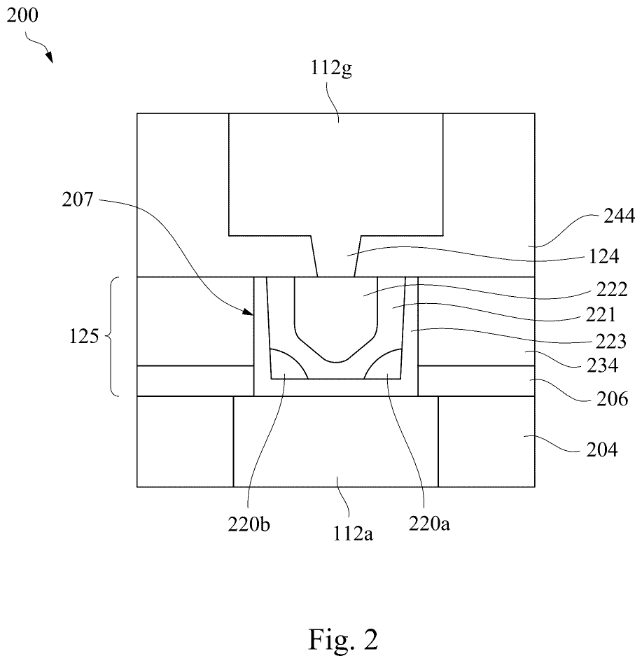

Reference is made to FIG. 2 to illustrate the structure of the RRAM cell 200. FIG. 2 illustrates a cross sectional view of a RRAM cell 200 of the RRAM device 100 of FIG. 1 in accordance with some embodiments of the present disclosure. In one or more embodiments of the present disclosure, the RRAM cell 200 is formed in a level of the BEVA 125. FIG. 2 further illustrates a level of the metal line 112a under the level of BEVA 125, a level of the TEVA 124 over the RRAM cell 200 in the BEVA 125 and a level of the metal line 112g formed over the TEVA 124.

As illustrated in FIG. 2, the RRAM device 100 includes the metal line 112a disposed within an insulating layer such as an inter-metal dielectric (IMD) layer 204. In some embodiments, the IMD layer 204 may include low-k dielectric layer such as porous silicon dioxide, fluorinated silica glass, polyimides, polynorbornenes, benzocyclobutene, or PTFE.

An etch stop layer (ESL) 206 is over the IMD layer 204. In some embodiments, the ESL 206 includes silicon carbide (SiC). An IMD layer 234 is formed over the ESL 206. An opening 207 may be formed through the ESL 206 and the IMD layer 234 and above the metal line 112a, and the RRAM cell 200 including the bottom electrode 223, the top electrode 222 and the resistance switchable layer 221 between the bottom electrode 223 and the top electrode 222 is formed in the opening 207 aligned with the metal line 112a. As illustrated in FIG. 2, the bottom electrode 223 may be formed along the inner sidewall of the opening 207 and the top surface of the metal line 112a through the IMD layer 234 and the ESL 206. The bottom electrode 223 may have an U-shaped profile. The spacers 220a and 220b, the resistance switchable layer 221 and the top electrode 222 may sequentially and conformally formed over the bottom electrode 223. The spacers 220a and 220b may be etched before forming the resistance switchable layer 221. The topmost surfaces of the IMD layer 234, the bottom electrode 223, the resistance switchable layer 221 and the top electrode 222 are level with each other.

In FIG. 2, an IMD layer 244 is formed over the IMD layer 234, the bottom electrode 223, the resistance switchable layer 221 and the top electrode 222. The TEVA 124 is formed over the RRAM cell 200 and is connected to the top electrode 222 and separated from the bottom electrode 223 and the resistance switchable layer 221. The bottom electrode 223 is a conductive layer between the TEVA 124 and the metal line 112a and thus can be regarded as a portion of the BEVA 125 connecting the RRAM cell 200 to the underlying metal line 112a. The metal line 112g is formed within the IMD layer 244 and over the TEVA 124. The TEVA 124 is connected between the top electrode 222 and the metal line 112g. The spacers 220a and 220b are between the resistance switchable layer 221 and the bottom electrode 223 and spaced apart from the IMD layer 234 and the ESL 206. The bottommost surfaces of the spacers 220a and 220b are higher than the bottommost surface of the ESL 206.

In some embodiments, the IMD layers 234 and 244 may be an extremely low-k dielectric layer such as porous silicon dioxide, fluorinated silica glass, polyimides, polynorbornenes, benzocyclobutene, or PTFE.

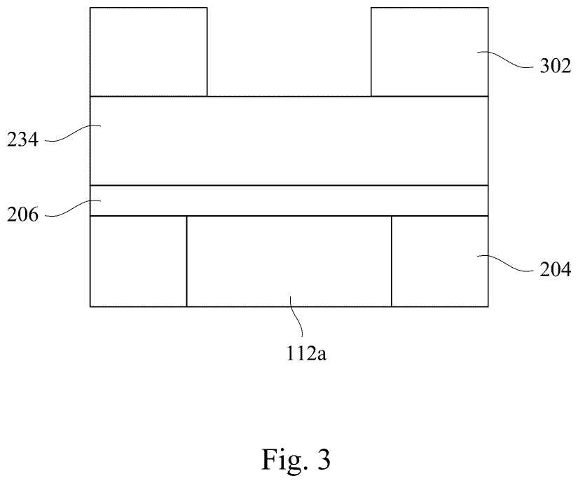

Reference is made to FIGS. 3 through 9 to illustrate cross-sectional views of formation of a RRAM cell 200 in accordance with some embodiments of the present disclosure.

As illustrated in FIG. 3, the metal line 112a is formed within the IMD layer 204. An ESL 206 is formed over the IMD layer 204 and the metal line 112a. In some embodiments, the ESL 206 may include SiC. An IMD layer 234 is formed over the ESL 206. In some embodiments, the IMD layer 234 may include extreme low-k dielectric material. The ESL 206 and the IMD layer 234 may be formed using suitable deposition process.

A patterned mask 302 with an opening is subsequently formed over the IMD layer 234 for patterning the IMD layer 234 and the ESL 206. The mask 302 may be formed using photolithography. The mask formed using lithography may be a photoresist mask but may also be a hard mask such as a nitride hard mask that is patterned using a photoresist mask.

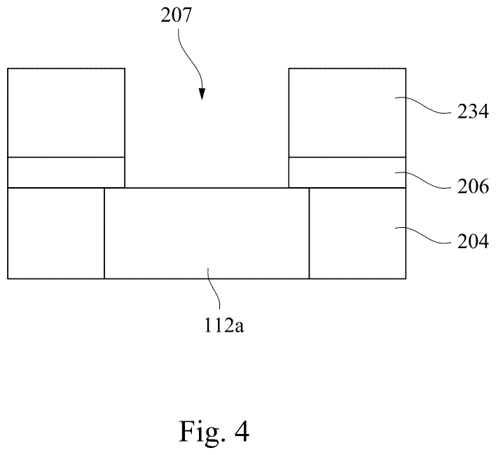

As illustrated in FIG. 4, after the mask 302 has been used to form an opening 207 in the IMD layer 234 and the etch stop layer then stripped away. The opening 207 is formed by etching areas of the IMD layer 234 and the ESL 206 that are left exposed by the patterned mask 302. The opening 207 exposes the metal line 112a within the IMD layer 204. In FIG. 4, the metal line 112a is wider than the opening 207.

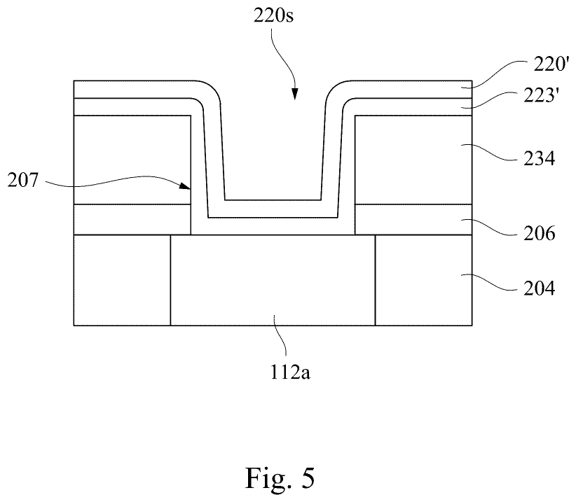

Continuing to FIG. 4, FIG. 5 illustrates that a bottom electrode layer 223′ is conformally formed over exposed top surface of IMD layer 234, inner sidewalls of the opening 207 through the IMD layer 234 and the ESL 206 and the exposed top surface of the metal line 112a. The bottom electrode layer 223′ may include titanium (Ti), tantalum (Ta), titanium nitride (TiN), tantalum nitride (TaN) or suitable conductive material. In some embodiments, the bottom electrode layer 223′ may be formed by a suitable deposition process. In some embodiments, the bottom electrode layer 223′ may be a material that is protected from copper diffusion by a diffusion barrier layer such as a TiN layer.

After the bottom electrode layer 223′ is formed, in one or more embodiments of the present disclosure, a spacer material is deposited over the bottom electrode layer 223′ to form a spacer layer 220′ entirely over the top surface of the bottom electrode layer 223′. In some embodiments, the spacer material includes silicon nitride (SiN), silicon carbide (SiC), silicon oxynitride (SiON) or any suitable dielectric material deposited over the bottom electrode layer 223′. As illustrated in FIG. 5, after the spacer layer 220′ is formed, the opening 207 is not completely filled and a recess 220s is between exposed opposite sidewalls of the formed spacer layer 220′ in the opening 207.

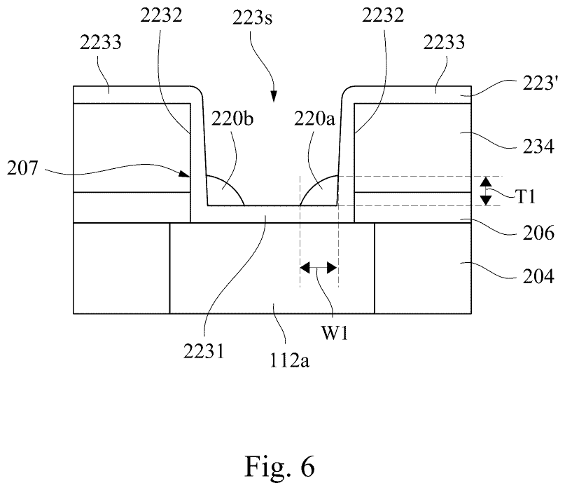

Continuing to FIG. 5, FIG. 6 illustrates etching the spacer layer 220′ to form spacers 220a and 220b. The bottom electrode layer 223′ includes a first portion 2231 over the metal line along a lateral direction, second portions 2232 extending along sidewalls of the IMD layer 234 and the ESL 206 and third portions 2233 over the IMD layer 234 along the lateral portions. In some embodiments, a top surface of the first portion 2231 is lower than an interface between the IMD layer 234 and the ESL 206. The first portion 2231 and the second portions 2232 of the bottom electrode layer 223′ may define a recess region 223s of the bottom electrode layer 223′. In FIG. 6, the spacer layer 220′ is etched so that portions of the spacer layer 220′ over third portions 2233 of the bottom electrode layer 223′ are removed, and a portion of the spacer layer 220′ over a center region of the first portion 2231 of the bottom electrode layer 223′ is removed, and portions of the spacer layer 220′ over upper sections of the second portions of the bottom electrode layer 223′ is removed.

In one or more embodiments of the present disclosure, residues of the etched spacer layers 220′ include spacers 220a and 220b. In FIG. 6, edge regions of the first portion 2231 and lower sidewalls of the second portions 2232 are covered by the spacers 220a and 220b. In one or more embodiments of the present disclosure, the spacers 220a and 220b may have similar shapes and sizes. As illustrated in FIG. 6, the spacers 220a and 220b have curved or convex surfaces arising from the etching process performed on the spacer layer 220′. In FIG. 6, the spacer 220a has a thickness T1 and a width W1. The thickness T1 of the spacer 220a is less than a total thickness of the ESL 206 and the IMD layer 234. The width W1 of the spacer 220a is less than a width of the opening 207 through the IMD layer 234 and the ESL 206. In FIG. 6, the width W1 of the spacer 220a is less than a width of the metal line 112a.

In one or more embodiments of the present disclosure, the spacer layer 220′ is etched by, for example, a dry etching process using plasma or a wet etching to form the spacers 220a and 220b. In FIG. 5, the recess 220s is formed and between the inner sidewalls of the spacer layer 220′ in the opening 207 so that the anisotropic etching process can be performed along the recess 220s to expose the bottom electrode layer 223′ from the spacer layer 220′. Etching rate of the etching process to the spacer layer 220′ is reduced near the inner sidewalls of the second portion 2232 of the bottom electrode layer 223′ so that the residues of the etched spacer layer 220′ remains near the inner sidewalls of the second portion 2232 of the bottom electrode layer 223′. The residues of the etched spacer layer 220′ may be regarded as spacers 220a and 220b, as illustrated in FIG. 6.

As illustrated in FIG. 5, during etching the spacer layer 220′, the bottom electrode layer 223′ overlaps the underlying IMD layer 234. The IMD layer 234 may be protected by the bottom electrode layer 223′ during etching the spacer layer 220′ so that plasma damage to the IMD layer 234 can be reduced.

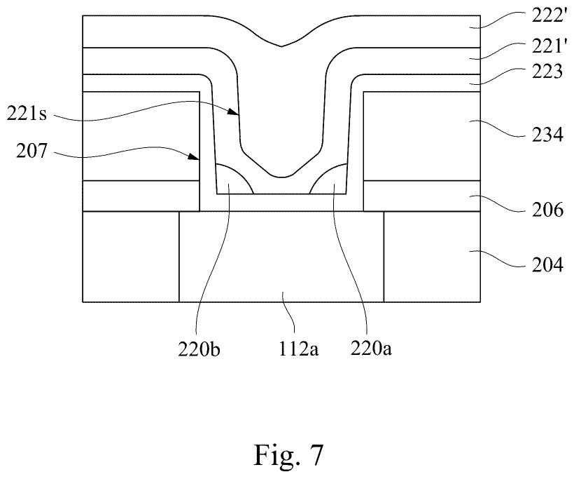

Continuing to FIG. 6, FIG. 7 illustrates forming a resistance switchable layer 221′ along the bottom electrode layer 223′, the spacers 220a and 220b. In some embodiments, the resistance switchable layer 221′ may be a resistive dielectric layer deposited over the bottom electrode layer 223′ and the spacers 220a and 220b. In some embodiments, variable resistive dielectric layer is a transitional metal oxide. Examples of materials that can be suitable for Variable resistive dielectric layer include NiOₓ, Ta_{y}Oₓ, TiOₓ, HfOₓ, WOₓ, ZrOₓ, Al_{y}Oₓ, and SrTiOₓ. Since the resistance switchable layer 221 is formed along the bottom electrode layer 223′, the spacers 220a and 220b, the resistance switchable layer 221 has a recess 221s extending into the opening 207 of the bottom electrode layer 223′.

After the resistance switchable layer 221 is formed, as illustrated in FIG. 7, a top electrode layer 222′ is formed over the resistance switchable layer 221. The top electrode layer 222′ may include titanium (Ti), tantalum (Ta), titanium nitride (TiN), tantalum nitride (TaN). In some embodiments, the top electrode layer 222′ may be formed by a suitable deposition process. In FIG. 7, the top electrode layer 222′ is filled with the recess 221s of the resistance switchable layer. The top electrode layer 222′ has the bottommost top surface higher that the topmost surfaces of the bottom electrode layer 223′ and the resistance switchable layer 221′.

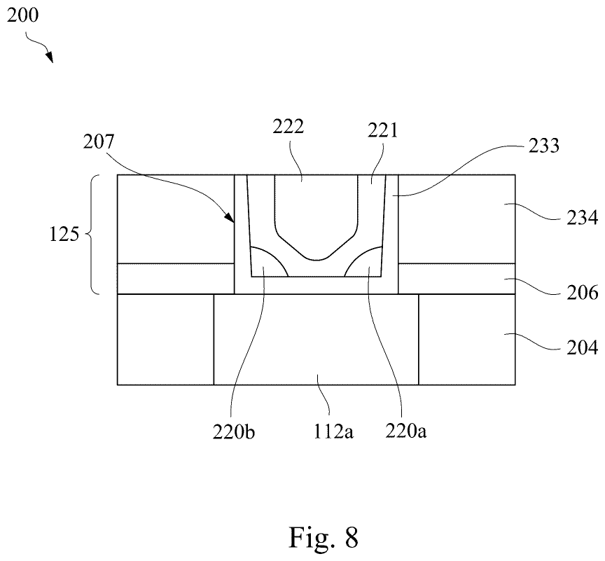

Continuing to FIG. 7, FIG. 8 illustrates a planarization process such as a chemical-mechanical planarization (CMP) is performed to the bottom electrode layer 223′, the resistance switchable layer 221′ and the top electrode layer 222′ higher than the top surface of the IMD layer 234. The CMP process is carried out to remove excess materials of the bottom electrode layer 223′, the resistance switchable layer 221′ and the top electrode layer 222′ outside the opening 207, while leaving a portion of the bottom electrode layer 223′ in the opening 207 to serve as a bottom electrode 223, leaving a portion of the resistance switchable layer 221′ in the opening 207 to serve as a resistance switchable layer 221, and leaving a portion of the top electrode layer 222′ to serve as a top electrode 222. As illustrated in FIG. 8, the third portions of the bottom electrode layer 223′ out of the opening 207 are removed. Therefore, after the planarization process is performed, the RRAM cell 200 is defined within the IMD layer 234 and the ESL 206. The bottom electrode 223 and the resistance switchable layer 221 have U-shaped profiles. The spacers 220a and 220b are between the bottom electrode 223 and the resistance switchable layer 221.

As illustrated in FIG. 8, the RRAM cell 200 includes the bottom electrode 223, the top electrode 222, the resistance switchable layer 221 between the bottom electrode 223 and the top electrode 222 and the spacers 220a and 220b between the bottom electrode 223 and the resistance switchable layer 221. The bottom electrode 223 extends through the IMD layer 234 and the ESL 206 may be regarded as a portion of the BEVA 125 in direct contact with the metal line 112a. The formed RRAM cell 200 is within a level of the BEVA 125 connected between the RRAM cell 200 and underlying metal line 112a.

A cell size of the RRAM cell 200 is the same as a size of the opening 207 and can be determined by the patterned mask 302 as illustrated in FIG. 3. The cell size of the RRAM cell 200 can thus be reduced based on the design of the patterned mask 302. In some embodiments, as illustrated in FIG. 8, a width of the RRAM cell 200 is less than a width of the metal line 112a.

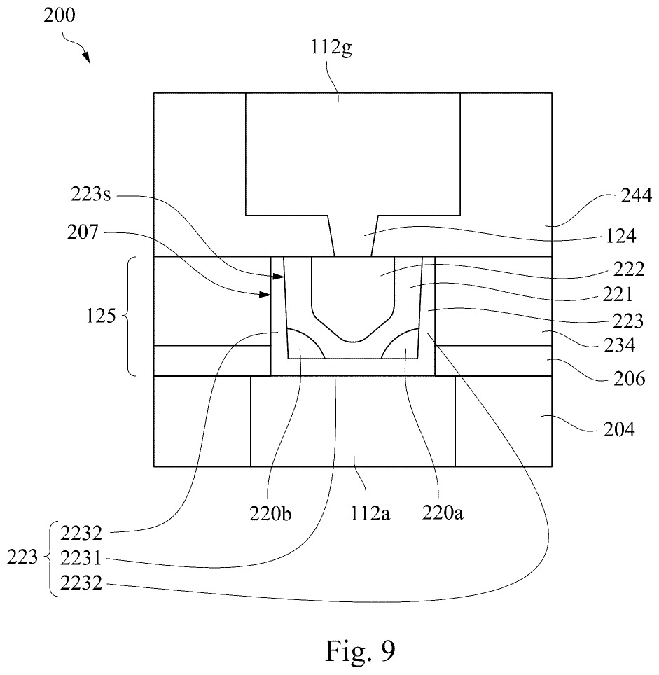

After the planarization process is performed to form the RRAM cell 200, in FIG. 9, a TEVA 124 is formed over the RRAM 200 and a metal line 112g is formed over the TEVA 124. In some embodiments, an IMD layer 244 is formed over the BEVA 125, and the TEVA 124 and the metal line 112g is formed within the IMD layer 244. In some embodiments, an IMD layer 244 is formed over the BEVA 125, and the TEVA 124 is formed in the IMD layer 244 and aligned with the top electrode 222. In FIG. 9, the TEVA 124 has tapered sidewalls extending to the top electrode 222. In some embodiments, the TEVA 124 may extend into the top electrode 222. A width of the TEVA 124 is less than a width of the top electrode 222 so that the TEVA 124 non-overlaps the resistance switchable layer 221 and the bottom electrode 223. In some embodiments, the TEVA 124 and the metal line 112g may be formed within the IMD layer 244 using a single and/or a dual damascene process, a via-first process, or a metal-first process. The TEVA 124 and the metal line 112g may be formed of a conductive material, such as copper, aluminum, titanium, the like, or a combination thereof, with or without a barrier layer.

As illustrated in FIG. 9, the bottom electrode 223 includes the first portion 2231 extending along a lateral direction and the second portions 2232 extending along sidewalls of the IMD layer 234 and the ESL 206. The second portions 2232 and the first portion 2231 collectively define a recess region 223s in the bottom electrode 223, with the first portion 2231 forming a bottom surface of the recessed region 223s. The spacers 220a and 220b are on the bottom surface of the recessed region 223s in the bottom electrode 223. The resistance switchable layer 221 of the resistive dielectric layer is on the bottom surface of the recess region 223s in the bottom electrode 223. The resistance switchable layer 221 of the resistive dielectric layer has a bottom surface spaced apart from the second portions 2232 of the bottom electrode 223 by the spacers 220a and 220b. The top electrode 222 is over the resistance switchable layer 221.

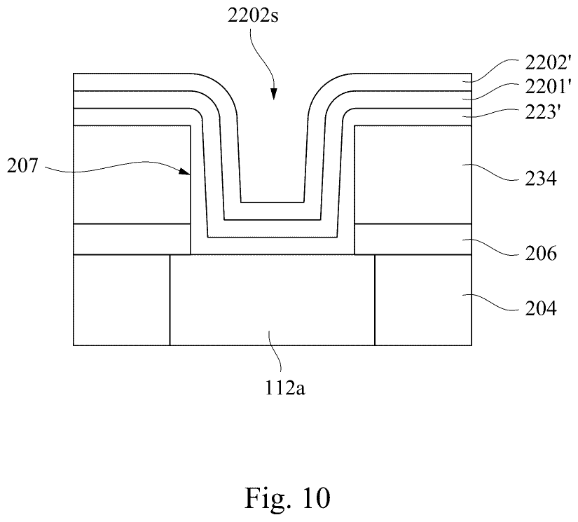

Reference is made to FIGS. 10 through 14 to illustrate cross-sectional views of formation of a RRAM cell 200 in accordance with some embodiments of the present disclosure.

Continuing to FIG. 4, FIG. 10 illustrates forming a bottom electrode layer 223′, a first spacer layer 2201′ and a second spacer layer 2202′ in the opening 207 through the IMD layer 234 and the ESL 206. The bottom electrode layer 223′ is conformally formed over exposed top surface of IMD layer 234, inner sidewalls of the opening 207 through the IMD layer 234 and the ESL 206 and the exposed top surface of the metal line 112a. After forming the bottom electrode layer 223′, the first spacer layer 2201′ is entirely formed over the top surface of the bottom electrode layer 223′, and the second spacer layer 2202′ is entirely formed over the top surface of the first spacer layer 2201′.

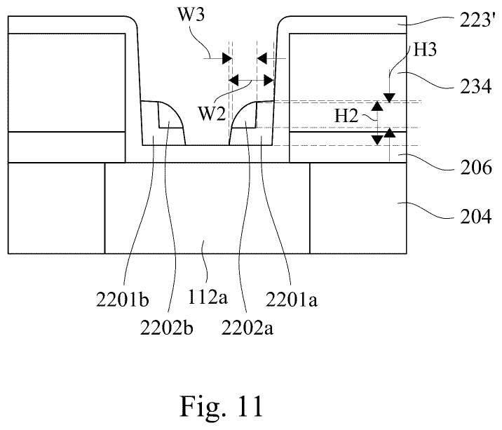

In some embodiments, the bottom electrode layer 223′ may include titanium (Ti), tantalum (Ta), titanium nitride (TiN), tantalum nitride (TaN) or suitable conductive material. In some embodiments, the bottom electrode layer 223′ may be formed by a suitable deposition process. In some embodiments, the first spacer layer 2201′ and the second spacer layer 2202′ may include silicon nitride (SiN), silicon carbide (SiC), silicon oxynitride (SiON) or any suitable dielectric material formed by a suitable deposition process. In some embodiments, the first spacer layer 2201′ and the second spacer layer 2202′ are made of different dielectric materials. Therefore, the first spacer layer 2201′ and the second spacer layer 2202′ can have different etch selectivity, thereby facilitating forming spacers with target geometry in subsequent etching step performed in FIG. 11.

As illustrated in FIG. 10, after the second spacer layer 2202′ is formed, the opening 207 is not completely filled and a recess 2202s is between exposed opposite sidewalls of the formed second spacer layer 2202′ in the opening 207.

As illustrated in FIG. 11, after the first spacer layer 2201′ and the second spacer layer 2202′ are formed, in FIG. 11, the first spacer layer 2201′ and the second spacer layer 2202′ are etched to expose the bottom electrode layer 223′. The first spacer layer 2201′ and the second spacer layer 2202′ out of the opening 207 and higher than the topmost top surface of the bottom electrode layer 223′ are removed. Upper inner sidewalls and a center bottom portion of the bottom electrode layer 223′ are exposed. In FIG. 11, the residue of the first spacer layer 2201′ forms first spacers 2201a and 2201b on opposite inner sidewall of the bottom electrode layer 223′, and the residue of the second spacer layer 2202′ forms second spacers 2202a and 2202b over the first spacers 2201a and 2201b, respectively.

In one or more embodiments of the present disclosure, the first spacer layer 2201′ and the second spacer layer 2202′ are etched by, for example, a dry etching process using plasma or a wet etching. In some embodiments, the first spacer layer 2201′ and the second spacer layer 2202′ can be etched by the same etching process. In FIG. 10, the recess 2202s is formed and between the inner sidewalls of the second spacer layer 2202′ in the opening 207, so that the anisotropic etching process can be performed along the recess 2202s to expose the bottom electrode layer 223′ from the first spacer layer 2201′ and the second spacer layer 2202′, as illustrated in FIG. 11. Etching rate of the etching process to the first spacer layer 2201′ and the second spacer layer 2202′ is reduced near the inner sidewalls of the bottom electrode layer 223′ so that the residues of the etched first spacer layer 2201′ and the etched second spacer layer 2202′ remains near the inner sidewalls of the bottom electrode layer 223′ to form the first spacers 2201a and 2201b and the second spacers 2202a and 2202b over the first spacers 2201a and 2201b.

In some embodiments, as illustrated in FIG. 11, the first spacer 2201a and 2201b may have L-shaped profile at the corner of the bottom electrode layer 223′. The second spacer 2202a is embedded within an L-shaped corner of the first spacer 2201a. The second spacer 2202b is embedded within an L-shaped corner of the first spacer 2201b. In the cross-section as illustrated in FIG. 11, each of the second spacers 2202a and 2202b has inner straight surfaces in contact with a corresponding one of the first spacers 2201a and 2201b and an outer round surface connected to the inner straight surfaces. In FIG. 11, the first spacer 2201a has a thickness T2 and a width W2. The second spacer 2202a has a thickness T3 less than the thickness T2 of the first spacer 2201a and a width W3 less than the width W2 of the first spacer 2201a. The thickness T2 of the first spacer 2201a is less than a total thickness of the IMD layer 234 and ESL 206. The width W2 of the first spacer 2201a is less than the opening 207 through the IMD layer 234 and the ESL 206. In FIG. 11, the width W2 of the first spacer 2201a is less than a width of the metal line 112a.

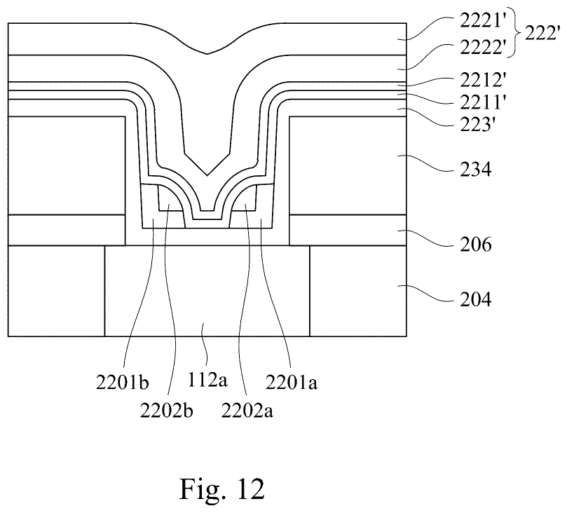

Continuing to FIG. 11, in FIG. 12, a resistive dielectric layer 2211′ and a capping layer 2212′ are conformally formed over the bottom electrode layer 223′, the first spacers 2201a and 2201b and the second spacers 2202a and 2202b. As shown in FIG. 12, the resistive dielectric layer 2211′ is formed and extending along the top surface of the bottom electrode layer 223′ above the top surface of the IMD layer 234, and the capping layer 2212′ is formed over the resistive dielectric layer 2211′.

In some embodiments, the resistive dielectric layer 2211′ may be a transitional metal oxide. Examples of materials that can be suitable for the resistive dielectric layer 2211′ may include NiOₓ, TayOₓ, TiOₓ, HfOₓ, WOₓ, ZrOₓ, AlyOₓ, and SrTiOₓ. In some embodiments, resistive dielectric layer 2211′ is a layer of material that is deposited over bottom electrode layer 223′. The capping layer 2212′ may provide an oxygen storage function that facilitates phase changes within the resistive dielectric layer 2211′. In some embodiments, the capping layer 2212′ is a metal or a metal oxide that is relatively low in oxygen concentration. Examples of metals that can be suitable for the capping layer 2212′ include Ti, Hf, Pt and Al. Examples of metal oxides that can be suitable for capping layer include TiOₓ, HfOₓ, ZrOₓ, GeOₓ, CeOₓ. The capping layer 2212′ can have any suitable thickness.

FIG. 12 illustrates forming a top electrode layer 222′ over the capping layer 2212′. In FIG. 12, the top electrode layer 222′ includes a first conductive layer 2222′ and a second conductive layer 2221′ sequentially formed over the capping layer 2212′. The first conductive layer 2222′ and the second conductive layer 2221′ overlap the top surface of the IMD layer 234. Therefore, the bottom electrode layer 223′, the first spacers 2201a and 2201b, the second spacers 2202a and 2202b, the resistive dielectric layer 2211′, the capping layer 2212′ and the top electrode layer 222′ including the first conductive layer 2222′ and the second conductive layer 2221′ are filled with the opening 207 through the IMD layer 234 and the ESL 206. In some embodiments, the first conductive layer 2222′ and the second conductive layer 2221′ of the top electrode layer 222′ may include titanium (Ti), tantalum (Ta), titanium nitride (TiN), tantalum nitride (TaN) formed by suitable deposition processes. In some embodiments, the top electrode layer 222′ may include more numbers of suitable conductive material layer. In some embodiments, the bottom electrode layer 223′ may further include one or more conductive layers.

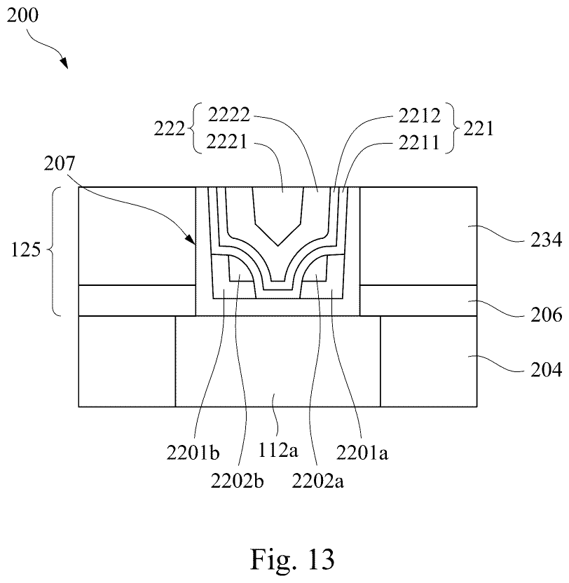

Continuing to FIG. 12, FIG. 13 illustrates a planarization process such as a CMP process is performed to the bottom electrode layer 223′, the resistive dielectric layer 2211′, the capping layer 2212′ and the first conductive layer 2222′ and the second conductive layer 2221′ of the top electrode layer 222′ higher than the top surface of the IMD layer 234. The CMP process is carried out to remove excess materials of the bottom electrode layer 223′, the resistive dielectric layer 2211′, the capping layer 2212′ and the first conductive layer 2222′and the second conductive layer 2221′ of the top electrode layer 222′ outside the opening 207, while leaving a portion of the bottom electrode layer 223′ in the opening 207 to serve as a bottom electrode 223, leaving portions of the resistive dielectric layer 2211′ and the capping layer 2212′ in the opening 207 to serve as a resistance switchable layer 221, and leaving portions of the first conductive layer 2222′and the second conductive layer 2221′ to serve as a top electrode 222. The resistance switchable layer 221 includes the residue 2211 of the resistive dielectric layer 2211′ (served as resistive dielectric layer 2211) and the residue 2212 of the capping layer 2212′ (served as capping layer 2212) in the opening 207. The top electrode 222 includes the residue 2222 of first conductive layer 2222′ (served as first conductive layer 2222) and the residue 2221 of the second conductive layer 2221′ (served as second conductive layer 2221) in the opening 207.

Therefore, after the CMP process is performed, the RRAM cell 200 is defined within the IMD layer 234 and the ESL 206. The RRAM cell 200 may include the bottom electrode 223, the top electrode 222 and the resistance switchable layer 221 between the top electrode 222 and the bottom electrode 223. The resistance switchable layer 221 may include the resistive dielectric layer 2211 and the capping layer 2212′. The top electrode 222 may include the first conductive layer 2222 and the As illustrated in FIG. 13, the first spacers 2201a and 2201b and the second spacers 2202a and 2202b are between the bottom electrode 223 and the resistance switchable layer 221 and spaced apart from the IMD layer 234.

A cell size of the RRAM cell 200 is the same as a size of the opening 207 and can be determined by the patterned mask 302 as illustrated in FIG. 3. The cell size of the RRAM cell 200 can thus be reduced based on the design of the patterned mask 302. In some embodiments, as illustrated in FIG. 13, a width of the RRAM cell 200 is less than a width of the metal line 112a.

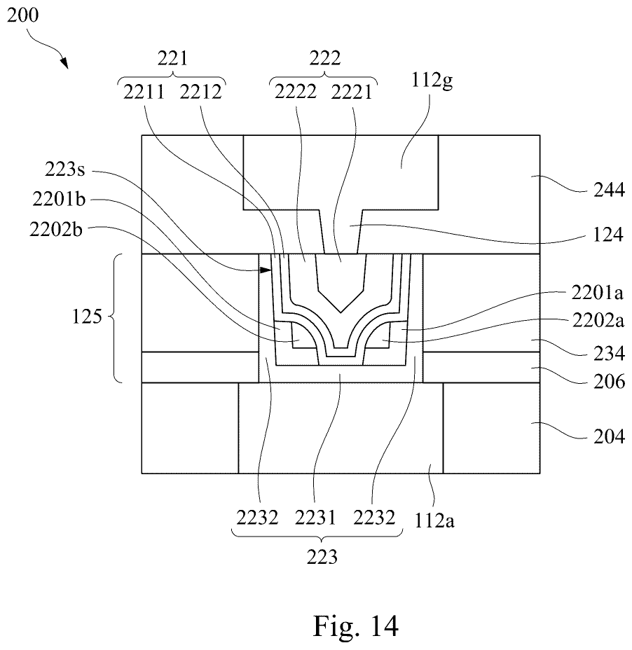

After the planarization process is performed to form the RRAM cell 200, in IG. 14, a TEVA 124 is formed over the RRAM 200 and a metal line 112g is formed over the TEVA 124. In some embodiments, an IMD layer 244 is formed over the BEVA 125, and the TEVA 124 and the metal line 112g is formed within the IMD layer 244. In some embodiments, an IMD layer 244 is formed over the BEVA 125, and the TEVA 124 is formed in the IMD layer 244 and aligned with the top electrode 222. In FIG. 14, the TEVA 124 has tapered sidewalls extending to the top electrode 222. In some embodiments, the TEVA 124 may extend into the top electrode 222. A width of the TEVA 124 is less than a width of the top electrode 222 so that the TEVA 124 non-overlaps the resistance switchable layer 221 and the bottom electrode 223. In some embodiments, the TEVA 124 and the metal line 112g may be formed within the IMD layer 244 using a single and/or a dual damascene process, a via-first process, or a metal-first process. The TEVA 124 and the metal line 112g may be formed of a conductive material, such as copper, aluminum, titanium, the like, or a combination thereof, with or without a barrier layer.

As illustrated in FIG. 14, the bottom electrode 223 includes a first portion 2231 extending along a lateral direction and second portions 2232 extending along sidewalls of the IMD layer 234 and the ESL 206. The second portions 2232 and the first portion 2231 collectively define a recess region 223s in the bottom electrode 223, with the first portion 2231 forming a bottom surface of the recessed region 223s. The first spacers 2201a and 2201b and the second spacers 2202a and 2202b are on the bottom surface of the recessed region 223s in the bottom electrode 223. The resistive dielectric layer 2211 and the capping layer 2212 of the resistance switchable layer 221 are on the bottom surface of the recess region 223s in the bottom electrode 223. The resistive dielectric layer 2211 has a bottom surface spaced apart from the second portions 2232 of the bottom electrode 223 by the spacers 220a and 220b. The top electrode 222 including the first conductive layer 2222 and the second conductive layer 2221 is over the resistance switchable layer 221.

In some embodiments, as illustrated in FIG. 14, the first spacer 2201a and 2201b has L-shaped profile at the corner of the second portions 2232 and the first portion 2231 of the bottom electrode 223. The second spacer 2202a is embedded within an L-shaped corner of the first spacer 2201a. The second spacer 2202b is embedded within an L-shaped corner of the first spacer 2201b.

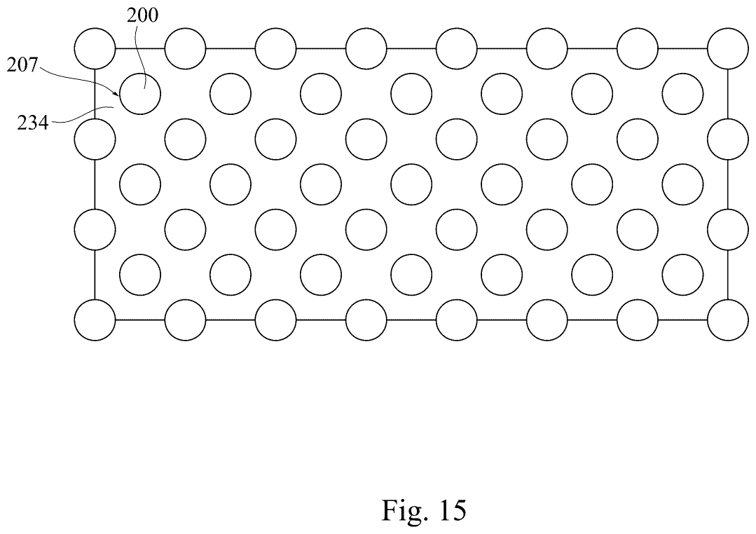

As illustrated in FIGS. 2 through 14, in one or more embodiments of the present disclosure, the RRAM cell (e.g., the RRAM cell 200 as illustrated in FIG. 8 or 13) may be formed within the dielectric layer (e.g., the IMD layer 234 and the ESL 206) of the level of BEVA and in direct contact with the underlying metal contact (e.g., the metal line 112a). The cell size of the formed RRAM cell may be controlled based on the opening through the dielectric layer of the level of the BEVA. Therefore, since the formed RRAM cells are embedded in the dielectric layer, the cell sizes of the formed RRAM cell 200 are determined when the openings 207 in which the RRAM cells 200 are formed within are defined and RRAM cell density can be increased. FIG. 15 illustrates a top view of a RRAM device in accordance with some embodiments of the present disclosure FIG. 15 illustrates a top view of a RRAM device in accordance with some embodiments of the present disclosure. As illustrated in FIG. 15, each of the RRAM cells 200 may be in the middle of immediately-adjacent four of the RRAM cells 200 so that the RRAM cells 200 may be arranged in a dense manner according to the arrangement to the openings 207, wherein each of the openings 207 may be in the middle of immediately-adjacent four of the openings 207.

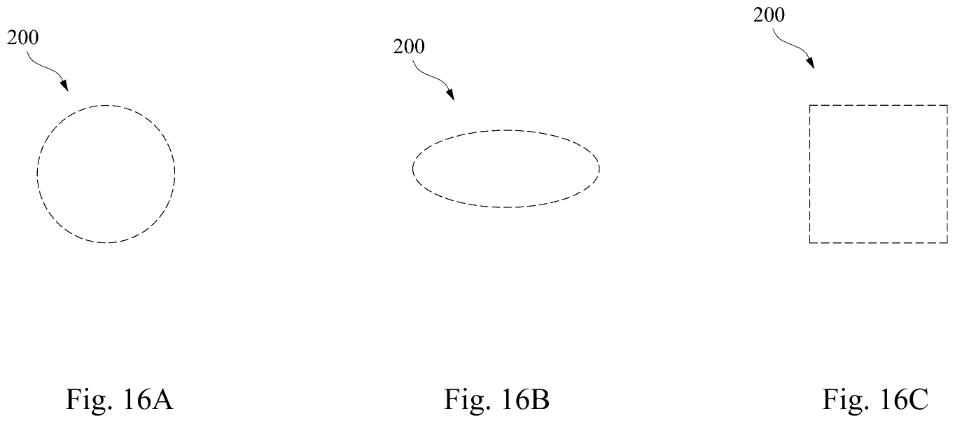

In one or more embodiments of the present disclosure, the cell profile of the formed RRAM cell may be controlled based on the opening through the dielectric layer of the level of the BEVA. FIGS. 16A through 16C illustrate top views of RRAM cells 200 in accordance with some embodiments of the present disclosure. FIG. 16A illustrates that the RRAM cell 200 has a circle-profile from a top view. FIG. 16B illustrates that the RRAM cell 200 has an oval-profile from a top view. FIG. 16C illustrates that the RRAM cell 200 has a rectangle profile from a top view.

According to one or more embodiments of the present disclosure, a method of forming a semiconductor device includes a number of operations. A first inter-metal dielectric (IMD) layer is formed over a first metal line. An opening is formed in the first IMD layer. A bottom electrode layer is formed in the opening of the first IMD layer. A first spacer layer is formed over the bottom electrode layer. The first spacer layer is etched to form first spacers within the opening in the first IMD layer. A resistive dielectric layer is formed over the bottom electrode layer and the first spacers. A top electrode is formed over the resistive dielectric layer. In one or more embodiments of the present disclosure, forming the top electrode includes depositing a top electrode layer overfilling the opening in the first IMD layer and performing a planarization process on the top electrode to remove a first portion of the top electrode layer outside the opening in the first IMD layer, while leaving a second portion of the top electrode layer in the opening in the first IMD layer. In some embodiments, the planarization process further removes a first portion of the resistive dielectric layer outside the opening in the first IMD layer, while leaving a second portion of the resistive dielectric layer in the opening in the first IMD layer. In some embodiments, the planarization process further removes a first portion of the bottom electrode layer outside the opening in the first IMD layer, while leaving a second portion of the bottom electrode layer in the opening in the first IMD layer. In some embodiments, the first metal line is wider than the second portion of the bottom electrode layer after performing the planarization process. In one or more embodiments of the present disclosure, the method further includes forming a second IMD layer over the first IMD layer and forming a via within the second IMD layer and over the top electrode, wherein the top electrode is wider than the via. In one or more embodiments of the present disclosure, the method further includes forming a second spacer layer over the first spacer layer and etching the second spacer layer to form second spacers within the opening in the first IMD layer. In some embodiments, one of the second spacers is embedded within an L-shaped corner of one of the first spacers. In one or more embodiments of the present disclosure, the top electrode includes more than one metal material. In one or more embodiments of the present disclosure, the method further includes forming a capping layer over the resistive dielectric layer. In one or more embodiments of the present disclosure, the method further includes forming an etch stop layer over the first metal line, wherein the opening is formed through the etch stop layer.

According to one or more embodiments of the present disclosure, a method of forming a semiconductor device includes a number of operations. A bottom electrode layer is formed in an opening of an IMD layer. A spacer layer is formed along the bottom electrode layer, wherein the spacer layer has a recess extending in the opening. The spacer layer is etched so that spacer residues of the spacer layer remain on opposite inner sidewalls of the bottom electrode layer. A resistance switchable layer is formed over the spacer residues and the bottom electrode layer. A top electrode layer is formed over the resistance switchable layer. A planarization process is performed on the top electrode layer, the resistance switchable layer and the bottom electrode layer to form a bottom electrode, a resistance switchable layer, and a top electrode confined in the opening in the IMD layer. In one or more embodiments of the present disclosure, forming the resistance switchable layer includes forming a resistive dielectric layer over the bottom electrode layer and the spacer residues. In some embodiments, forming the resistive switchable layer further includes forming a capping layer over the resistive dielectric layer.

According to one or more embodiments of the present disclosure, a semiconductor device includes a first IMD layer and a RRAM cell embedded in the first IMD layer. The RRAM cell includes a bottom electrode, spacers, a resistive dielectric layer and a top electrode. The bottom electrode includes a first portion extending along a lateral direction and second portions extending along sidewalls of the first IMD layer. The second portions and the first portion collectively define a recess region in the bottom electrode, with the first portion forming a bottom surface of the recessed region. The spacers are on the bottom surface of the recessed region in the bottom electrode. The resistive dielectric layer is on the bottom surface of the recess region in the bottom electrode. The resistive dielectric layer has a bottom surface spaced apart from the second portions of the bottom electrode by the spacers. The top electrode is over the resistive dielectric layer. In one or more embodiments of the present disclosure, a topmost surface of the bottom electrode is level with a topmost surface of the resistive dielectric layer. In one or more embodiments of the present disclosure, the semiconductor device further includes a second IMD layer and a first metal line. The second IMD layer is below the first IMD layer. The first metal line is within the second IMD layer. The RRAM cell is over the first metal line. The first metal line is wider than the RRAM cell. In some embodiments, the semiconductor device further includes a third IMD layer and via. The third IMD layer is over the first IMD layer. The via is within the third IMD layer and over the top electrode. The top electrode is wider than the via. In some embodiments, the spacer is spaced apart from the second IMD layer. In one or more embodiments of the present disclosure, the RRAM cell further includes a capping layer between the top electrode and the resistive dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first inter-metal dielectric (IMD) layer over a first metal line;
forming an opening in the first IMD layer;
forming a bottom electrode layer in the opening of the first IMD layer;
forming a first spacer layer over the bottom electrode layer;
etching the first spacer layer to form first spacers within the opening in the first IMD layer;
forming a resistive dielectric layer over the bottom electrode layer and the first spacers; and
forming a top electrode over the resistive dielectric layer.

2. The method of claim 1, wherein forming the top electrode comprises:
depositing a top electrode layer overfilling the opening in the first IMD layer; and
performing a planarization process on the top electrode to remove a first portion of the top electrode layer outside the opening in the first IMD layer, while leaving a second portion of the top electrode layer in the opening in the first IMD layer.

3. The method of claim 2, wherein the planarization process further removes a first portion of the resistive dielectric layer outside the opening in the first IMD layer, while leaving a second portion of the resistive dielectric layer in the opening in the first IMD layer.

4. The method of claim 2, wherein the planarization process further removes a first portion of the bottom electrode layer outside the opening in the first IMD layer, while leaving a second portion of the bottom electrode layer in the opening in the first IMD layer.

5. The method of claim 4, wherein the first metal line is wider than the second portion of the bottom electrode layer after performing the planarization process.

6. The method of claim 1, further comprising:
forming a second IMD layer over the first IMD layer; and
forming a via within the second IMD layer and over the top electrode, wherein the top electrode is wider than the via.

7. The method of claim 1, further comprising:
forming a second spacer layer over the first spacer layer; and
etching the second spacer layer to form second spacers within the opening in the first IMD layer.

8. The method of claim 7, wherein one of the second spacers is embedded within an L-shaped corner of one of the first spacers.

9. The method of claim 1, wherein the top electrode comprises more than one metal material.

10. The method of claim 1, further comprising:
forming a capping layer over the resistive dielectric layer.

11. The method of claim 1, further comprising:
forming an etch stop layer over the first metal line, wherein the opening is formed through the etch stop layer.

12. A method, comprising:
forming a bottom electrode layer in an opening of an IMD layer;
forming a spacer layer along the bottom electrode layer, wherein the spacer layer has a recess extending in the opening;
etching the spacer layer so that spacer residues of the spacer layer remain on opposite inner sidewalls of the bottom electrode layer;
forming a resistance switchable layer over the spacer residues and the bottom electrode layer;
forming a top electrode layer over the resistance switchable layer; and
performing a planarization process on the top electrode layer, the resistance switchable layer and the bottom electrode layer to form a bottom electrode, a resistance switchable layer, and a top electrode confined in the opening in the IMD layer.

13. The method of claim 12, wherein forming the resistance switchable layer comprises:
forming a resistive dielectric layer over the bottom electrode layer and the spacer residues.

14. The method of claim 13, wherein forming the resistive switchable layer further comprises:
forming a capping layer over the resistive dielectric layer.

15. A semiconductor device, comprising:
a first IMD layer; and
a RRAM cell embedded in the first IMD layer, comprising:
a bottom electrode comprising a first portion extending along a lateral direction and second portions extending along sidewalls of the first IMD layer, wherein the second portions and the first portion collectively define a recessed region in the bottom electrode, with the first portion forming a bottom surface of the recessed region;
spacers on the bottom surface of the recessed region in the bottom electrode;
a resistive dielectric layer on the bottom surface of the recessed region in the bottom electrode, the resistive dielectric layer having a bottom surface spaced apart from the second portions of the bottom electrode by the spacers; and
a top electrode over the resistive dielectric layer.

16. The semiconductor device of claim 15, wherein a topmost surface of the bottom electrode is level with a topmost surface of the resistive dielectric layer.

17. The semiconductor device of claim 15, further comprising:
a second IMD layer below the first IMD layer; and
a first metal line within the second IMD layer, wherein the RRAM cell is over the first metal line, and the first metal line is wider than the RRAM cell.

18. The semiconductor device of claim 17, further comprising:
a third IMD layer over the first IMD layer; and
a via within the third IMD layer and over with the top electrode, wherein the top electrode is wider than the via.

19. The semiconductor device of claim 17, wherein the spacers are spaced apart from the second IMD layer.

20. The semiconductor device of claim 15, wherein the RRAM cell further comprises:
a capping layer between the top electrode and the resistive dielectric layer.
